(19) United States
(12) Patent Application Publication
(10) Pub. No.: US 2023/0214669 A1
(43) Pub. Date: Jul. 6, 2023

(54) HYBRID SEARCH TO TRAIN MEMORY AND HIGH-SPEED INPUT/OUTPUT INTERFACES

(71) Applicant: Intel Corporation, Santa Clara, CA (US)

(72) Inventors: Wenzhi WANG, Shanghai (CN); Yunhui CHU, Hillsboro, OR (US); James A. McCALL, Portland, OR (US); Chunfei YE, Lacey, WA (US); Tonia M. ROSE, Wendell, NC (US); Caroline GRIMES, Raleigh, NC (US)

(21) Appl. No.: 18/120,848

(22) Filed: Mar. 13, 2023

(30) Foreign Application Priority Data
Feb. 22, 2023 (WO) PCT/CN2023/077600

(51) Int. Cl. G06N 5/01; H03K 19/00

(52) U.S. Cl. CPC G06N 5/01; H03K 19/0005

(57) ABSTRACT

Decision feedback equalization (DFE) training time in a memory device is reduced through the use of a hybrid search to select values of tap coefficients for taps in the DFE. The hybrid search includes two searches. A first search is performed to identify initial values of tap coefficients, a second search uses the initial values of tap coefficients to find the final values of tap coefficients.

### CLAIM OF PRIORITY

The present application claims the benefit of priority to PCT Application No. PCT/CN23/77600 filed Feb. 22, 2023, the entire disclosure of which is incorporated herein by reference.

### FIELD

This disclosure relates to memory and high-speed Input/Output interfaces and in particular to training of memory and high-speed Input/Output interfaces.

### BACKGROUND

A data eye refers to the average time between a rising edge of a data signal and a subsequent falling edge. Memory subsystems continue to be designed for increasingly higher frequencies for data access, and more specifically, for the transfer of data between the memory device and an associated memory controller. Higher data rates mean the frequency between rising and falling edges increases, and shifting phases due to noise results in enough variation of the timing of rising and falling edges that on the average there is no opening between rising and falling edges of the data signal (that is, the data eye is closed).

### BRIEF DESCRIPTION OF THE DRAWINGS

Features of embodiments of the claimed subject matter will become apparent as the following detailed description proceeds, and upon reference to the drawings, in which like numerals depict like parts, and in which:

FIG. 1 is a block diagram of an embodiment of a memory subsystem in a system;

FIG. 2 is a block diagram of an embodiment of a memory device;

FIG. 3 is a block diagram of an embodiment of a memory device with decision feedback equalization (DFE);

FIG. 4 is a flowgraph illustrating a method performed during training to determine the values of the DFE coefficients for the taps in the filter shown in FIG. 3;

FIG. 5 is a graph illustrating the relationship between Figure of Merit (FOM) (y-axis) and tap settings (x-axis) used to perform the modified binary search to select a start value for the tap setting for the Tabu search;

FIG. 6 is a flow graph of the modified binary search to select a start value for the tap setting for the Tabu search;

FIG. 7 is a graph illustrating a numerical example of the relationship between Figure of Merit (FOM) (y-axis) and tap settings (x-axis) used to perform the modified binary search to select a start value for the tap setting for the Tabu search;

FIG. 8 is a flow graph of the Tabu search to select a final value for the tap setting; and

FIG. 9 is a block diagram of an embodiment of a computer system that includes the memory module that includes the memory device controller.

Although the following Detailed Description will proceed with reference being made to illustrative embodiments of the claimed subject matter, many alternatives, modifications, and variations thereof will be apparent to those skilled in the art. Accordingly, it is intended that the claimed subject matter be viewed broadly, and be defined as set forth in the accompanying claims.

### DESCRIPTION OF EMBODIMENTS

As the data rate for the transfer of data on data (DQ) signals between the memory device and an associated memory controller increases (for example, above 2933 Mega. Transfers per second (MT/s)). signal degradation due to Inter Symbol Interference (ISI) may increase and the data eye at a DQ input on the memory device may be closed. Equalization can be used to help improve (or open up) the data eye at the DQ input after the data is latched by a receiver in the memory device.

One approach to recovering the data signal with a collapsed data eye is to implement filtering at the receiver, such as decision feedback equalization (DFE) (where DFE can alternatively refer to a decision feedback equalizer that implements the decision feedback equalization). DFE can improve signaling even at higher data rates. A n-tap decision feedback equalization (DFE) can be used to help equalize the DQ signals without amplifying the noise due to insertion loss and reflections.

As buffer complexity increases, more DFE taps need to be trained. A line search algorithm that is currently used to train DFE taps is becoming insufficient for searching and finding the global optimum solution in a high-dimensional space. As the number of memory channels per socket increases, training requires more time to complete. For example, 8 memory channels per socket takes about 96 seconds to complete the DDR5 Tx and Rx DFE training steps, which is 40% of the boot time landing zone (4 minutes). The projected DFE training time for 12 memory channels per socket is 60% of the boot time landing zone. This makes the overall system design very challenging.

Decision feedback equalization (DFE) training time in a memory device is reduced through the use of a hybrid search to select values of tap coefficients for taps in the DFE. The hybrid search includes two searches. A first search is performed to identify initial values of tap coefficients, a second search uses the initial values of tap coefficients to find the final values of tap coefficients.

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

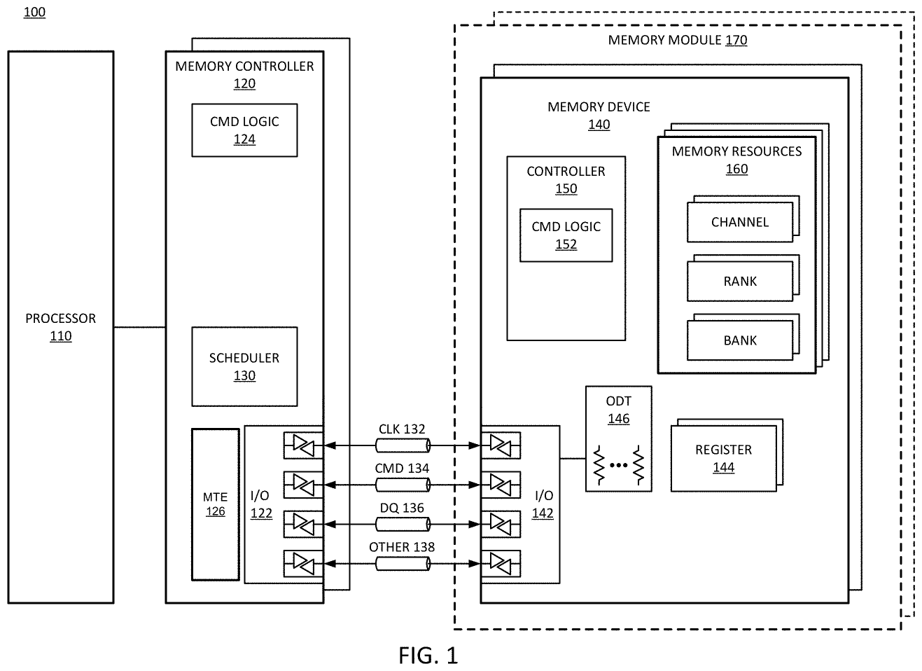

FIG. 1 is a block diagram of an embodiment of a memory subsystem in a system 100. System 100 includes a processor 110 and elements of a memory subsystem in a computing device. Processor 110 represents a processing unit of a computing platform that may execute an operating system (OS) and applications, which can collectively be referred to as the host or the user of the memory. The OS and applications execute operations that result in memory accesses. Processor 110 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 100 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, originally published in September 2012 by JEDEC), DDR5 (DDR version 5, originally published in July 2020), LPDDR3 (Low Power DDR version 3, JESD209-3B, August 2013 by JEDEC), LPDDR4 (LPDDR version 4, JESD209-4, originally published by JEDEC in August 2014), LPDDR5 (LPDDR version 5, JESD209-5A, originally published by JEDEC in January 2020), WIO2 (Wide Input/Output version 2, JESD229-2 originally published by JEDEC in August 2014), HBM (High Bandwidth Memory, JESD235, originally published by JEDEC in October 2013), HBM2 (HBM version 2, JESD235C, originally published by JEDEC in January 2020), or HBM3 (HBM version 3 currently in discussion by JEDEC), or others or combinations of memory technologies, and technologies based on derivatives or extensions of such specifications. The JEDEC standards are available at www.jedec.org.

Descriptions herein referring to a “RAM” or “RAM device” can apply to any memory device that allows random access, whether volatile or nonvolatile. Descriptions referring to a “DRAM” or a “DRAM device” can refer to a volatile random access memory device. The memory device or DRAM can refer to the die itself, to a packaged memory product that includes one or more dies, or both. In one embodiment, a system with volatile memory that needs to be refreshed can also include nonvolatile memory.

Memory controller 120 represents one or more memory controller circuits or devices for system 100. Memory controller 120 represents control logic that generates memory access commands in response to the execution of operations by processor 110. Memory controller 120 accesses one or more memory devices 140. Memory devices 140 can be DRAM devices in accordance with any referred to above. In one embodiment, memory devices 140 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. As used herein, coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one embodiment, settings for each channel are controlled by separate mode registers or other register settings. In one embodiment, each memory controller 120 manages a separate memory channel, although system 100 can be configured to have multiple channels managed by a single controller, or to have multiple controllers on a single channel. In one embodiment, memory controller 120 is part of host processor 110, such as logic implemented on the same die or implemented in the same package space as the processor.

Memory controller 120 includes I/O (Input/Output) interface logic 122 to couple to a memory bus, such as a memory channel as referred to above. I/O interface logic 122 (as well as I/O interface logic 142 of memory device 140) can include pins, pads, connectors, signal lines, traces, or wires, or other hardware to connect the devices, or a combination of these. I/O interface logic 122 can include a hardware interface. As illustrated, I/O interface logic 122 includes at least drivers/transceivers for signal lines. Commonly, wires within an integrated circuit interface couple with a pad, pin, or connector to interface signal lines or traces or other wires between devices. I/O interface logic 122 can include drivers, receivers, transceivers, or termination, or other circuitry or combinations of circuitry to exchange signals on the signal lines between the devices. I/O interface logic 122 can also be referred to as Double Data Rate IO (DDRIO) logic. The memory controller 120 includes a Memory Training Engine (MTE) to train the I/O interface logic 122. The exchange of signals includes at least one of transmit or receive. While shown as coupling I/O interface logic 122 from memory controller 120 to I/O interface logic 142 of memory device 140, it will be understood that in an implementation of system 100 where groups of memory devices 140 are accessed in parallel, multiple memory devices can include I/O interfaces to the same interface of memory controller 120. In an implementation of system 100 including one or more memory modules 170, I/O interface logic 142 can include interface hardware of the memory module in addition to interface hardware on the memory device itself. Other memory controllers 120 can include separate interfaces to other memory devices 140.

The bus between memory controller 120 and memory devices 140 can be implemented as multiple signal lines coupling the memory controller 120 to memory devices 140. The bus may typically include at least clock (CLK) 132, command/address (CMD) 134, and write and read data (DQ) 136, and zero or more other signal lines 138. In one embodiment, a bus or connection between memory controller 120 and memory can be referred to as a memory bus. The signal lines for CMD can be referred to as a “C/A bus” (or ADD/CMD bus, or some other designation indicating the transfer of commands (C or CMD) and address (A or ADD) information) and the signal lines for write and read data DQ can be referred to as a “data bus.” In one embodiment, independent channels have different clock signals, C/A buses, data buses, and other signal lines. Thus, system 100 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 120 and memory devices 140. An example of a serial bus technology is 8B10B encoding and transmission of high-speed data with embedded clock over a single differential pair of signals in each direction. In one embodiment, CMD 134 represents signal lines shared in parallel with multiple memory devices. In one embodiment, multiple memory devices share encoding command signal lines of CMD 134, and each has a separate chip select (CS_n) signal line to select individual memory devices.

It will be understood that in the example of system 100, the bus between memory controller 120 and memory devices 140 includes a subsidiary command bus CMD 134 and a subsidiary bus to carry the write and read data, DQ 136. In one embodiment, the data bus can include bidirectional lines for read data and for write/command data. In another embodiment, the subsidiary bus DQ 136 can include unidirectional write signal lines for write and data from the host to memory, and can include unidirectional lines for read data from the memory to the host. In accordance with the chosen memory technology and system design, other signal lines 138 may accompany a bus or sub bus, such as strobe lines DQS. Based on design of system 100, or implementation if a design supports multiple implementations, the data bus can have more or less bandwidth per memory device 140. For example, the data bus can support memory devices that have either a x32 interface, a x16 interface, a x8 interface, or other interface. The convention “xW,” where W is an integer that refers to an interface size or width of the interface of memory device 140, which represents a number of signal lines to exchange data with memory controller 120. The interface size of the memory devices is a controlling factor on how many memory devices can be used concurrently per channel in system 100 or coupled in parallel to the same signal lines. In one embodiment, high bandwidth memory devices, wide interface devices, or stacked memory configurations, or combinations, can enable wider interfaces, such as a x128 interface, a x256 interface, a x512 interface, a x1024 interface, or other data bus interface width.

In one embodiment, memory devices 140 and memory controller 120 exchange data over the data bus in a burst, or a sequence of consecutive data transfers. The burst corresponds to a number of transfer cycles, which is related to a bus frequency. In one embodiment, the transfer cycle can be a whole clock cycle for transfers occurring on a same clock or strobe signal edge (e.g., on the rising edge). In one embodiment, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length 8 (BL8), and each memory device 140 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

Memory devices 140 represent memory resources for system 100. In one embodiment, each memory device 140 is a separate memory die. In one embodiment, each memory device 140 can interface with multiple (e.g., 2) channels per device or die. Each memory device 140 includes I/O interface logic 142, which has a bandwidth determined by the implementation of the device (e.g., x16 or x8 or some other interface bandwidth). I/O interface logic 142 enables the memory devices to interface with memory controller 120. I/O interface logic 142 can include a hardware interface, and can be in accordance with I/O interface logic 122 of memory controller, but at the memory device end. In one embodiment, multiple memory devices 140 are connected in parallel to the same command and data buses. In another embodiment, multiple memory devices 140 are connected in parallel to the same command bus, and are connected to different data buses. For example, system 100 can be configured with multiple memory devices 140 coupled in parallel, with each memory device responding to a command, and accessing memory resources 160 internal to each. For a Write operation, an individual memory device 140 can write a portion of the overall data word, and for a Read operation, an individual memory device 140 can fetch a portion of the overall data word. As non-limiting examples, a specific memory device can provide or receive, respectively, 8 bits of a 128-bit data word for a Read or Write transaction, or 8 bits or 16 bits (depending for a x8 or a x16 device) of a 256-bit data word. The remaining bits of the word will be provided or received by other memory devices in parallel.

In one embodiment, memory devices 140 are disposed directly on a motherboard or host system platform (e.g., a PCB (printed circuit board) on which processor 110 is disposed) of a computing device. In one embodiment, memory devices 140 can be organized into memory modules 170. In one embodiment, memory modules 170 represent dual inline memory modules (DIMMs). In one embodiment, memory modules 170 represent other organization of multiple memory devices to share at least a portion of access or control circuitry, which can be a separate circuit, a separate device, or a separate board from the host system platform. Memory modules 170 can include multiple memory devices 140, and the memory modules can include support for multiple separate channels to the included memory devices disposed on them. In another embodiment, memory devices 140 may be incorporated into the same package as memory controller 120, such as by techniques such as multi-chip-module (MCM), package-on-package, through-silicon via (TSV), or other techniques or combinations. Similarly, in one embodiment, multiple memory devices 140 may be incorporated into memory modules 170, which themselves may be incorporated into the same package as memory controller 120. It will be appreciated that for these and other embodiments, memory controller 120 may be part of host processor 110.

Memory devices 140 each include memory resources 160. Memory resources 160 represent individual arrays of memory locations or storage locations for data. Typically, memory resources 160 are managed as rows of data, accessed via word line (rows) and bit line (individual bits within a row) control. Memory resources 160 can be organized as separate channels, ranks, and banks of memory. Channels may refer to independent control paths to storage locations within memory devices 140. Ranks may refer to common locations across multiple memory devices (e.g., same row addresses within different devices). Banks may refer to arrays of memory locations within a memory device 140. In one embodiment, banks of memory are divided into sub-banks with at least a portion of shared circuitry (e.g., drivers, signal lines, control logic) for the sub-banks. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one embodiment, memory devices 140 include one or more registers 144. Register 144 represents one or more storage devices or storage locations that provide configuration or settings for the operation of the memory device. In one embodiment, register 144 can provide a storage location for memory device 140 to store data for access by memory controller 120 as part of a control or management operation. In one embodiment, register 144 includes one or more Mode Registers. In one embodiment, register 144 includes one or more multipurpose registers. The configuration of locations within register 144 can configure memory device 140 to operate in a different “mode,” where command information can trigger different operations within memory device 140 based on the mode. Additionally, or in the alternative, different modes can also trigger different operation from address information or other signal lines depending on the mode. Settings of register 144 can indicate configuration for I/O settings (e.g., timing, termination or ODT (on-die termination) 146, driver configuration, or other I/O settings).

In one embodiment, memory device 140 includes ODT 146 as part of the interface hardware associated with I/O interface logic 142. ODT 146 can be configured as mentioned above, and provide settings for impedance to be applied to the interface to specified signal lines. In one embodiment, ODT 146 is applied to DQ signal lines. In one embodiment, ODT 146 is applied to command signal lines. In one embodiment, ODT 146 is applied to address signal lines. In one embodiment, ODT 146 can be applied to any combination of the preceding. The ODT settings can be changed based on whether a memory device is a selected target of an access operation or a non-target device. ODT 146 settings can affect the timing and reflections of signaling on the terminated lines. Careful control over ODT 146 can enable higher-speed operation with improved matching of applied impedance and loading. ODT 146 can be applied to specific signal lines of I/O interface logic 142, 122, and is not necessarily applied to all signal lines.

Memory device 140 includes controller 150, which represents control logic within the memory device to control internal operations within the memory device. For example, controller 150 decodes commands sent by memory controller 120 and generates internal operations to execute or satisfy the commands. Controller 150 can be referred to as an internal controller, and is separate from memory controller 120 of the host. Controller 150 can determine what mode is selected based on register 144, and configure the internal execution of operations for access to memory resources 160 or other operations based on the selected mode. Controller 150 generates control signals to control the routing of bits within memory device 140 to provide a proper interface for the selected mode and direct a command to the proper memory locations or addresses. Controller 150 includes command logic 152, which can decode command encoding received on command and address signal lines. Thus, command logic 152 can be or include a command decoder. With command logic 152, memory device can identify commands and generate internal operations to execute requested commands.

Referring again to memory controller 120, memory controller 120 includes scheduler 130, which represents logic or circuitry to generate and order transactions to send to memory device 140. From one perspective, the primary function of memory controller 120 can be considered to schedule memory access and other transactions to memory device 140. Such scheduling can include generating the transactions themselves to implement the requests for data by processor 110 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands, or a combination.

Memory controller 120 typically includes logic to allow selection and ordering of transactions to improve performance of system 100. Thus, memory controller 120 can select which of the outstanding transactions should be sent to memory device 140 in which order, which is typically achieved with logic much more complex that a simple first-in first-out algorithm. Memory controller 120 manages the transmission of the transactions to memory device 140, and manages the timing associated with the transaction. In one embodiment, transactions have deterministic timing, which can be managed by memory controller 120 and used in determining how to schedule the transactions.

Referring again to memory controller 120, memory controller 120 includes command (CMD) logic 124, which represents logic or circuitry to generate commands to send to memory devices 140. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 140, memory controller 120 can issue commands via I/O interface logic 122 to cause memory device 140 to execute the commands. In one embodiment, controller 150 of memory device 140 receives and decodes command and address information received via I/O interface logic 142 from memory controller 120. Based on the received command and address information, controller 150 can control the timing of operations of the logic and circuitry within memory device 140 to execute the commands. Controller 150 is responsible for compliance with standards or specifications within memory device 140, such as timing and signaling requirements. Memory controller 120 can implement compliance with standards or specifications by access scheduling and control.

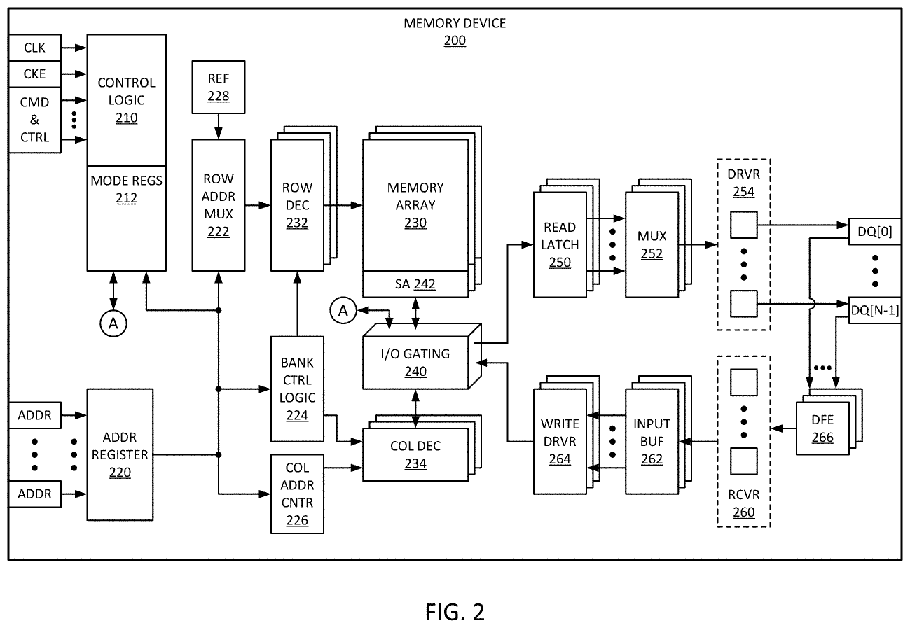

FIG. 2 is a block diagram of an embodiment of a memory device 200. Memory device 200 represents one example of a memory device in accordance with memory devices 140 of system 100. In one embodiment, memory device 200 is a DRAM device mounted to a substrate to connect to a CPU as in-package memory.

Address (addr) register 220 receives address information (ADDR) such as row address and bank address signals to identify the portion of memory that is to be affected by a particular command. The address, clock (CLK), clock enable (CKE), and command (CMD) and control (CTRL) signals represent I/O connectors for command and address for memory device 200. Control logic 210 receives CLK, CKE, and CMD, and controls the operation of memory device 200 in relation to those signals. In one embodiment, address register 220 distributes the address information to row address multiplexer (row addr mux) 222, bank control (ctrl) logic 224, and column address counter (col addr cntr) 226. Row address mux 222 takes the row address information and a refresh counter (ref 228) as input, and controls the row address latch (RAL) and decoder (row decoder 232) for each bank of the memory device. Bank control logic 224 selects the bank that is selected for the memory access operation (e.g., based on the command) received. Column address counter 226 generates a signal to select the column for the operation.

Row decoder (dec) 232 selects an address in a bank, which can include a row of memory array 230. In one embodiment, memory array 230 can be or include subarrays. Signals from bank control logic 224 and column address counter 226 can trigger column decoder (col dec) 234 to activate the appropriate sense amplifiers (SA) 242 for the desired memory array 230. Column decoder (col dec) 234 can trigger I/O gating 240, which represent the hardware including signal lines or wires as well as logic to route data to and from memory arrays 230. I/O gating 240 can place data into sense amplifiers 242 for a write operation, and can read the data out for a read operation. Column decoder 234 makes a column selection for I/O gating 240 based on bank control logic selection and the column address counter selection.

In one embodiment, read latch 250 is coupled to receive data bits from I/O gating 240 for a read operation. Read latch 250 feeds the data into mux 252, which can select the number of bits corresponding to the device data interface. Mux 252 can send the data to driver (drvr) 254, which will drive the data on I/O connectors DQ[0:(N−1)]. While not specifically illustrated, it will be understood that driver 254 can drive on or more data strobe lines based on the timing.

For a write operation, the controller provides data on DQ[0:(N−1)]. In one embodiment, receiver (rcvr) 260 receives write data from the data bus, and inputs it into input register or input buffer 262. Input buffer (buf) 262 samples the data in accordance with a data strobe line, and can latch the data to write driver (drvr) 264, which provides the data to I/O gating 240.

Memory device 200 includes mode registers (regs) 212 that store configuration information to control various operational modes for memory device 200. Control logic 210 can operate based on settings stored in mode registers 212. Memory device 200 includes DFE 266 to provide filtering for receive data. The filtering can operate to “open” the data eye for data signals received by receiver 260. DFE 266 operates based on configuration information stored in mode registers 212 DFE 266 represents the DFE circuits to apply to receiver 260. It will be understood that there can be a DFE circuit for each of the N data signal lines DQ.

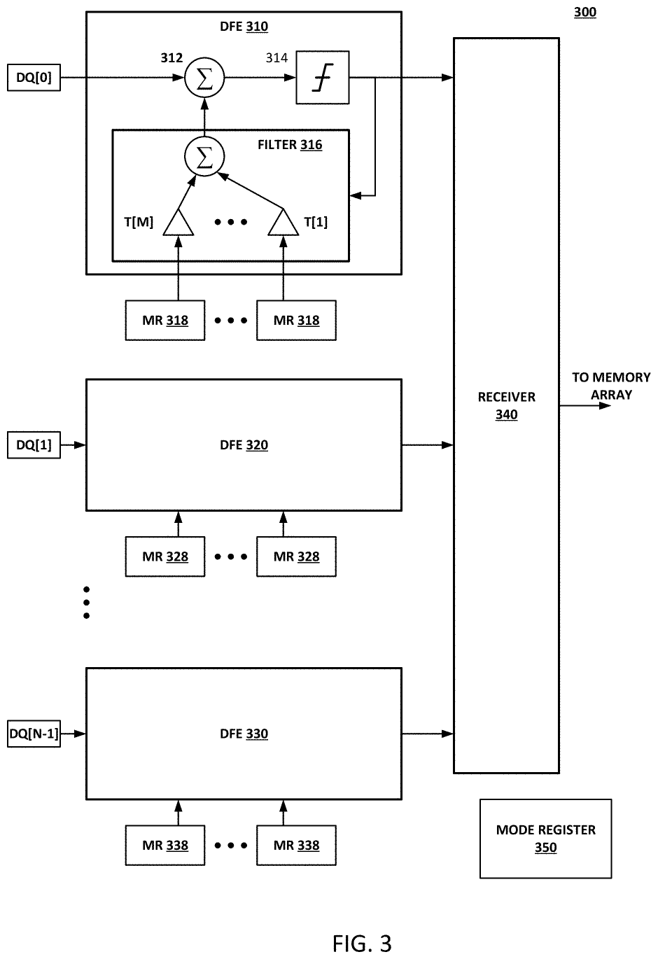

FIG. 3 is a block diagram of an embodiment of a memory device with decision feedback equalization. System 300 can be one example of a memory device in accordance with any embodiment described herein, such as memory device 140 of FIG. 1 or memory device 200 of FIG. 2. System 300 illustrates components of receive I/O for the memory device. More specifically, system 300 illustrates N data signal line interfaces, DQ[N−1:0]. In one embodiment, system 300 includes DFE between the data signal line interface and receiver circuitry 340. In one embodiment, each signal line has separate DFE circuitry, as illustrated by DFE 310 on the input path of DQ[0], DFE 320 on the input path of DQ[1], and DFE 330 on the input path of DQ[N−1]. Only the details of DFE 310 are illustrated, but the other DFE components can be similar or the same.

The DFE circuitry provides filtered data to receiver circuitry 340 for further processing by the memory device, and to perform operations on the memory array based on the received commands. The memory device of system 300 can include mode registers (MR) 350.

In one embodiment, DFE 310 includes summation circuit 312 at its front end, decision slicer circuit 314 at its back end, and filter 316. Filter 316 can be referred to as a feedback path or a tapped feedback path that includes multiple taps for multiple previously sampled digital bit values. DFE 310 can remove inter symbol interference (ISI) to reduce distortion for a received high speed digital signal stream on DQ[0].

Very high speed digital pulses tend to lose their sharp rectangular shape as they propagate along a signal trace, resulting in more drawn out, wider, rounder shapes by the time they are received at the receiving end. The wider rounded pulses can extend into the time slot of neighboring pulses. The pulse shape of any pulse can therefore become even more corrupted by the interfering waveforms of its neighboring pulses in the digital stream.

In one embodiment, filter 316 includes M “taps” T[M:1] in a feedback loop, where the different taps can be specifically tuned to remove interference from a preceding pulse or a pulse that was received ahead of the current pulse whose digital value is being determined. Decision slicer circuit 314 determines the digital value (1 or 0) of the digital pulse that is currently being received. The M taps have associated coefficients Wn to configure the tap for removing interference from a preceding digital pulse. In one embodiment, the coefficients are determined for each tap and stored in corresponding mode registers 318.

The coefficients can capture the amplitude (or amount) of a prior pulse that interferes with the current pulse, and summation circuit 312 subtracts the particular amplitude from the currently received signal. The subtraction ideally completely removes any or all interference from the prior pulses. In one embodiment, the taps are designed for specific previously received signals. For example, tap T[1] can be configured to remove interference from an immediately preceding received signal, T[2] from the received signal prior to that, and so forth. The DFE can be configured to remove interference from as many preceding signals as determined for a system, with one tap per preceding signal. In one embodiment, DFE 310 includes two taps. In another embodiment, DFE 310 includes four taps. In yet another embodiment, DFE 310 includes six taps. Other numbers of taps are possible.

It will be understood that with different signal paths for the different data bits, the DFE coefficients can be different for each tap, and for each DFE circuit. Thus, the group of mode register 318 stores configuration information for DFE 310, and more specifically for the different taps of filter 316. Similarly, mode registers 328 provide configuration for taps of a filter path for DFE 320. Similarly, mode registers 338 provide configuration for taps of a filter path for DFE 330.

System 300 determines the values of the various coefficients during training, such as in conjunction with boot up. The host associated with system 300 (not specifically shown) can determine the coefficients and write them to the various mode registers.

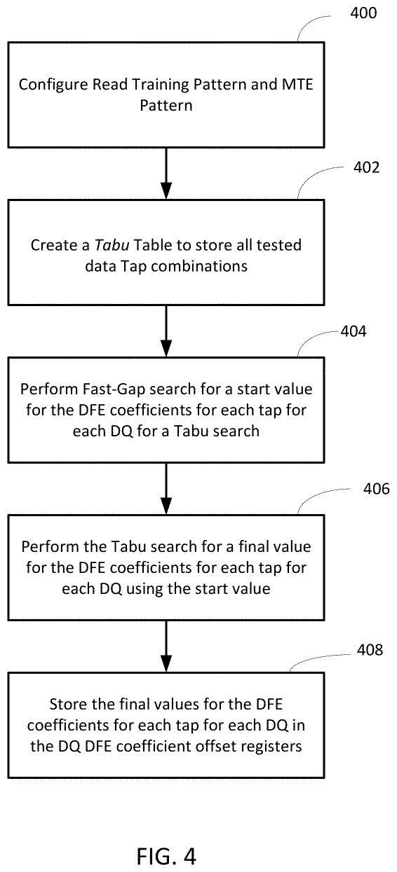

FIG. 4 is a flowgraph illustrating a method performed during read DFE training to determine the values of the DFE coefficients for the taps. Read DFE training is used to tune the Host side Receiver DFE. Read DFE Training is performed during initialization of the memory module and during operation of the memory module upon changes to interacting parameters such as, changes to continuous time linear equalization (CTLE), On Die Termination (ODT) changes, or any other parameters that may change the swing of the signal, the common mode of the signal, or the channel behavior.

At block 400, the DRAM Read Training Pattern is configured in the mode registers in the memory controller and the Memory Training Engine (MTE) Pattern in the MTE 126 is configured to match the DRAM Read Training Pattern.

At block 402, a Tabu table is created in the memory controller 120 to store all tested data Tap combinations and the Per-DQ FOM for the tested data taps including the tested data taps collected during the modified binary search.

At block 404, for each Tap, the per DQ predicted starting point is found for each tap using the modified binary search. The per DQ dfe_coeff setting for the current Tap is set to the PredictedStartPoint before moving to the next tap. The current best tap setting is stored in the correct index of the BestCurrentTapSolution=[Tap1, Tap2, Tap3, Tap4, Tap5, Tap6] in the Tabu table. For example, BestCurrentTapSolution=[32, 16, 0, 0, 0, 0] after Tap1 sweep the best setting is 32, after Tap2 sweep the best setting is 16.

At block 406, after completing the modified binary search for all Tap Coefficients, the Tabu search is performed with BestCurrentTapSolution and TabuList as the starting point. The per DQ Best Tap Solution is found for all Tap Coefficients using the Tabu Sweep Method. DFE Gain can be added as a variable in the solution space for determining neighbors.

At block 408, program the final tap values to the per nibble and per DQ DFE coefficient offset registers. For Read DFE training for the receiver in the memory controller 120, the DFE coefficient offset registers are in the I/O interface logic 122. For Write DFE training for the receiver in the memory module 170, DFE coefficient offset registers are set in the mode registers 212 of the memory module 170, and the settings impact the operation of the DFE 266.

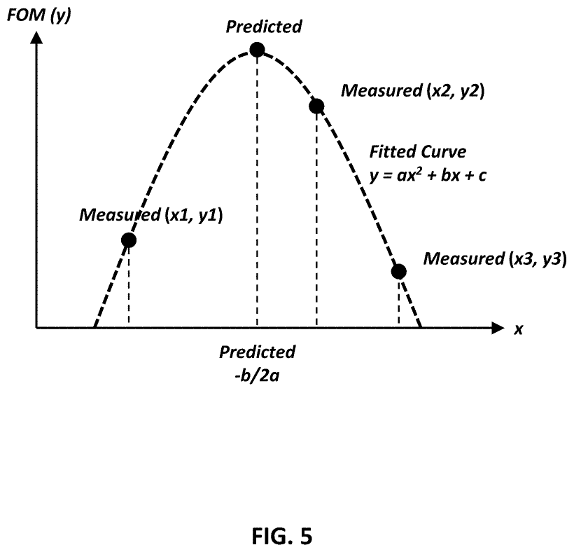

FIG. 5 is a graph illustrating the relationship between Figure of Merit (FOM) (y-axis) and tap settings (x-axis) used to perform the modified binary search to select a start value for the tap setting for the Tabu search. For each test point (x,y), x is the tap setting for the test point and y is the FOM measured at x.

A figure of merit (FOM) is a quantity used to characterize the performance of a device, system or method. relative to its alternatives. MTE and DRAM features can be used to collect Rx margins as a Figure of Merit. For example. Rx margins can include RxVref Eye. Height (RxVref Top Edge−RxVref Bottom Edge), RxDQS Eye width (RxDqs Right Edge−RxDqs Left Edge), area of the eye passing region (sum of all the RxVref Eye Heights at each RxDQS Offset), Max Rx Vref (max RxVref Eye Height at any RxDQS Offset).

Each FOM data point is associated with (that is, the tap setting combination is set and a measurement or series of measurements is made to determine the Figure of Merit) a combination of settings for the Rx DFE Tap Coefficients. For example, in a system with 6 Rx DFE Tap Coefficients the FOM is N for a combination of Tap1=1, Tap2=0, Tap3=0, Tap4=0, Tap5=0, Tap6=0 settings. The set of FOM data points collected across both the modified binary search and the Tabu search method is used to determine the final tap coefficient combination.

The modified binary search is performed using tap-coefficients (for example, Tap1, . . . Tap6) to select the next tap setting to be the middle of the biggest gap of untested tap settings. FOM is measured at tap settings for test points (x1, y1), (x2, y2), (x3, y3). For each test point (x,y), x is the tap setting for the test point and y is the FOM measured at x.

The search. through the tap-coefficients to select a start value for the tap setting for the Tabu search is performed until the Gap Stop Condition is met or the High in the Middle, and Low on the Sides (HMLS) condition is met. The Gap Stop Condition is met when x1=x2−1 and x2=x3−1 for test points (x1, y1), (x2, y2), (x3, y3). The HMLS condition is reached when y1 and y2 and y3 are greater than 0, x3>x2>x1, y2>=y1, and y2>=y3 for test points (x1, y1), (x2, y2), (x3, y3).

Once the HMLS stop condition has been met, the start value for the tap setting for the Tabu search (also referred to as the predicted best tap setting) is calculated by solving the quadratic function y=ax²+bx+c, for the coefficients a, b and c using the test points (x1, y1), (x2, y2), (x3, y3).

$$[ \begin{matrix}a \\ b \\ c\end{matrix} ] = {[ \begin{matrix}{x}_{1}^{2} & {x}_{1} & 1 \\ {x}_{2}^{2} & {x}_{2} & 1 \\ {x}_{3}^{2} & {x}_{3} & 1\end{matrix} ]}^{- 1} \cdot [ \begin{matrix}{y}_{1} \\ {y}_{2} \\ {y}_{3}\end{matrix} ]$$

The coefficients a, b and c are used to compute the predicted best tap setting (predicted best tap setting=compute round(−b/2a)). Ideally the HMLS stop condition is met after the first three test points have been measured.

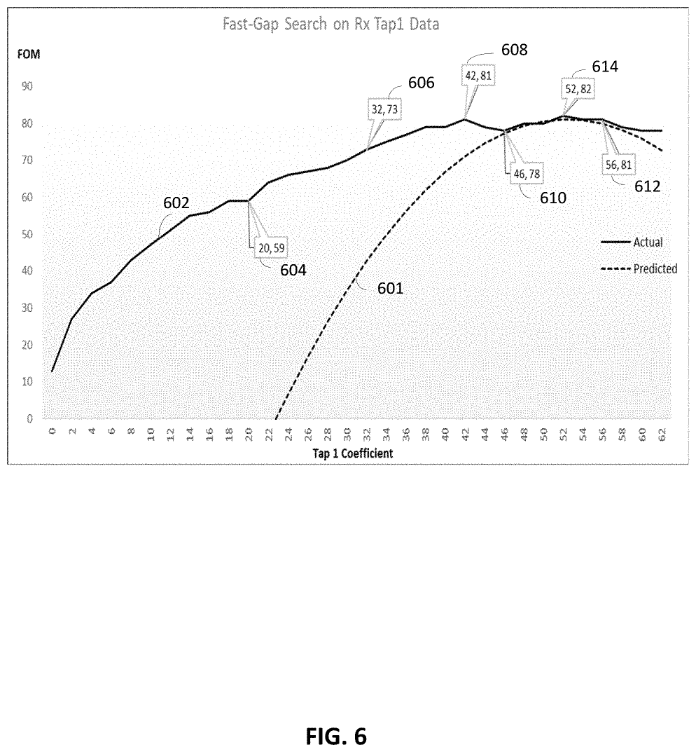

FIG. 6 is a graph illustrating a numerical example of the relationship between Figure of Merit (FOM) (y-axis) and tap settings (x-axis) used to perform the modified binary search to select a start value for the tap setting for the Tabu search. The graph includes test points (20, 59), (32,73), (42, 81), (46, 78), (52, 82) and (56, 81) for a tap coefficient with a value between 0 and 64. For the numerical example shown in FIG. 6, three iterations of the modified binary search are performed using three test points (x1, y1), (x2, y2), (x3, y3) in each iteration as shown in Table 1 below to select a start value for the tap setting for the Tabu search.

TABLE 1

| Iteration | (x1, y1) | (x2, y2) | (x3, y3) |
|---|---|---|---|
| 1 | (20, 59) | (0, 0) | (42, 81) |
| 2 | (32, 73) | (42, 81) | (52, 82) |
| 3 | (46, 78) | (52, 82) | (56, 81) |

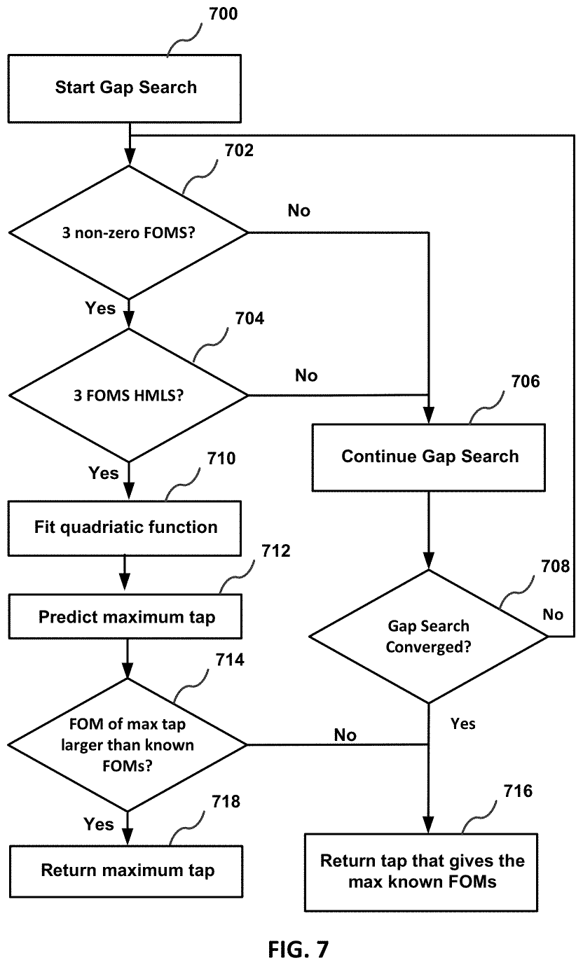

FIG. 7 is a flow graph of the modified binary search to select a start value for the tap setting for the Tabu search. FIG. 7 will be described in conjunction with the numerical examples shown in FIG. 6 for a tap coefficient with a value between 0 and 64.

Prior to starting the first iteration to measure the FOM at three test points, the tap setting and FOM for test point (x2, y2) is initialized to (0,0), the tap setting x1 for test point (x1, y2) is set to 20 (the maximum tap coefficient (64) divided by 3) and the tap setting for test point (x3, y3) is set to 42 ((the maximum tap coefficient (64) multiplied by 2) divided by 3). In the example of the binary search described in conjunction with FIG. 7, some of the computed numerical values of the test points are incremented/decremented to an even number to simplify the computation for the numerical example.

At block 700, FOM is measured at tap settings for three test points (x1, y1), (x2, y2), (x3, y3). In the first iteration, test point (x2, y2) is (0, 0) (the minimum tap setting and minimum FOM), x1 is 20 (64 (the maximum tap setting) divided by 3), and x3 is 42 ((64 (the maximum tap setting) multiplied by 2) divided by 3). The FOM at tap setting x1 and tap setting x3 is measured, y1 is 59 and y3 is 81. The values of the three test points (x1, y1), (x2, y2), (x3, y3) are (20, 59), (0, 0) and (42, 81).

In the first iteration, at block 702, y1 is 59, y2 is 0 and y3 is 81. As all FOMs (y1, y2, y3) are not non-zero, processing continues with block 706.

In the first iteration, at block 706, new test points (x1,y1), (x2,y2) and (x3,y3) are selected for the second iteration using the test points for the first iteration. Test points (x3, y3) (42,81) used for the first iteration are selected as test points (x2, y2) (42,81) for the second iteration. Tap setting x1(20) used in the first iteration is selected as the minimum tap setting for the second iteration.

In the second iteration, test point (x2, y2) is (42, 81), x1 is 32 (x2(42)−((x2 (42)−minimum tap setting (20)) divided by 2)), and x3 is 52 (x2(42)+((max tap setting (64)−x2(42) divided by 2). The FOM at tap setting x1 and tap setting x3 is measured, y1 is 73 and y3 is 82. The values of the three test points (x1, y1), (x2, y2), (x3, y3) are (32, 73), (42, 81) and (52, 82). Processing continues with block 708.

For the second iteration, at block 702, y1 is 73, y2 is 81 and y3 is 82. All FOMs (y1, y2, y3) are non-zero, processing continues with block 704.

In the second iteration, at block 704, y1 is 73, y2 is 81 and y3 is 82. FOMs (y1, y2, y3) are not HMLS because the condition y2>=y3 is not met (y2(81) is not greater than y3(82)), processing continues with block 706.

For the second iteration, at block 708, the values of x1 and x3 are checked for the stop condition. The stop condition is not met because x1(32) is not equal to x2(42) minus 1 and x3 (52) is not equal to x2(42) plus 1. Processing continues to block 702 for the second iteration.

After the second iteration, at block 706, new test points (x1,y1), (x2,y2) and (x3,y3) are selected for the third iteration using the test points for the second iteration. Test points (x3, y3) (52,82) used for the second iteration are selected as test points (x2, y2) (52,82) for the second iteration. Tap setting x1(32) used in the second iteration is selected as the minimum tap setting for the third iteration.

In the third iteration, test point (x2, y2) is (52, 82), x1 is 46 (x2(52)−((x2 (52)−minimum tap setting (42)) divided by 2)), and x3 is 58 (x2(52)+((max tap setting (64)−x2(52) divided by 2). The FOM at tap setting x1 and tap setting x3 is measured, y1 is 78 and y3 is 81. The values of the three test points (x1, y1), (x2, y2), (x3, y3) are (46, 78), (52, 82) and (58, 81).

For the third iteration, at block 702, y1 is 73, y2 is 82 and y3 is 81. All FOMs (y1, y2, y3) are non-zero, processing continues with block 704.

In the third iteration, at block 704, processing continues with block 710. The HMLS condition is reached. y1(78) and y2(82) and y3(81) are greater than 0, x3(58)>x2(52)>x1(46), y2 (52)>=y1(46), and y2 (82)>=y3 (81) for test points (x1, y1), (x2, y2), (x3, y3). Processing continues with block 710.

At block 710. once the HMLS stop condition has been met, the start value for the tap setting for the Tabu search (also referred to as the predicted best tap setting) is calculated by solving the quadratic function y=ax²+bx+c, for the coefficients a, b and c using the test points (x1, y1), (x2, y2), (x3, y3), where x1=46, y1=78, x2=52, y2=82, x3=58 and y3=81.

$$[ \begin{matrix}a \\ b \\ c\end{matrix} ] = {[ \begin{matrix}{x}_{1}^{2} & {x}_{1} & 1 \\ {x}_{2}^{2} & {x}_{2} & 1 \\ {x}_{3}^{2} & {x}_{3} & 1\end{matrix} ]}^{- 1} \cdot [ \begin{matrix}{y}_{1} \\ {y}_{2} \\ {y}_{3}\end{matrix} ]$$

a=−0.175, b=18.65, c=−414.6. Processing continues with block 712.

At block 712, the start value for the tap setting for the Tabu search is computed. Start value=round(−b/2a)=53. Processing continues with block 714.

At block 714, if the FOM for the computed tap setting is larger than all known FOMs, processing continues with block 714. If not, processing continues with block 716.

At block 716, the tap setting associated with the largest known FOM is returned as the start value for the tap setting for the Tabu search.

At block 718, the computed tap setting is returned as the start value for the tap setting for the Tabu search.

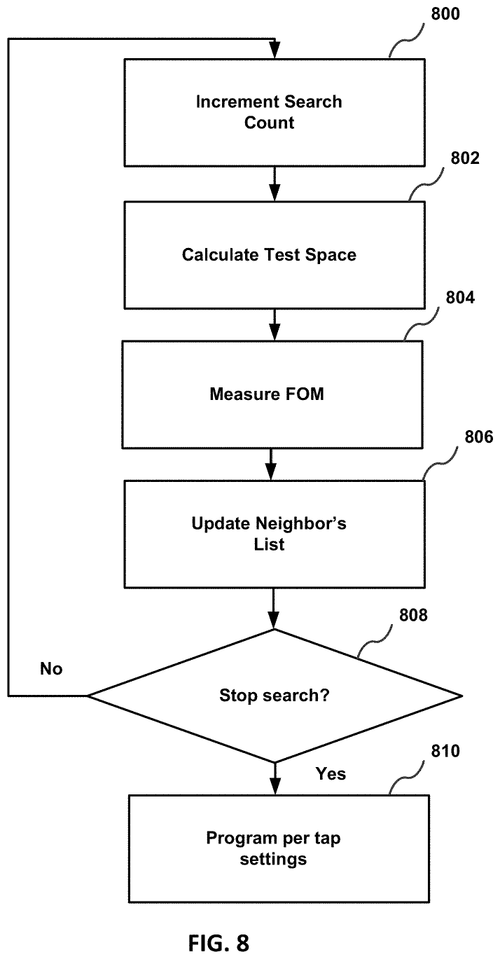

FIG. 8 is a flow graph of the Tabu search to select a final value for the tap setting. Tabu is an optimized search method that combines a neighborhood search with a tabu list. The neighborhood search is the process of choosing the next test points as the immediate neighbors to a current best solution space. The tabu list includes all the tap settings already searched in the modified binary search (for example, TabuList={[Tap1, Tap2, Tap3, Tap4, Tap5, Tap6]: FOM}. The tap settings in the TabuList are not used by the Tabu search so that the Tabu search is not performed in suboptimal regions. The starting point for the Tabu search is the BestCurrentTapSolution=[Tap1, Tap2, Tap3, Tap4, Tap5, Tap6] as determined by the modified binary search.

At block 800, a TabuSearchCount that is initialized to 0 keeps track of the number of neighborhood iterations that have been performed. The TabuSearchCount is incremented. Processing continues with block 802.

At block 802, the NeighborhoodDistance (the search distance from the current tap settings) is +/−1. A test space is generated based on the neighboring Tap settings as shown below in a neighbors array:

Neighbors={[Tap1+1,Tap2,Tap3,Tap4,Tap5,Tap6],[Tap1 −1,Tap2,Tap3,Tap4,Tap5,Tap6],[Tap1,Tap2+1,Tap3,Tap4,Tap5,Tap6],[Tap1,Tap2 −1,Tap3,Tap4,Tap5,Tap6],[Tap1,Tap2,Tap3+1,Tap4,Tap5,Tap6],[Tap1,Tap2,Tap3 −1,Tap4,Tap5,Tap6],[Tap1,Tap2,Tap3,Tap4+1,Tap5,Tap6],[Tap1,Tap2,Tap3,Tap4 −1,Tap5,Tap6],[Tap1,Tap2,Tap3,Tap4,Tap5+1,Tap6],[Tap1,Tap2,Tap3,Tap4,Tap5 −1,Tap6],[Tap1,Tap2,Tap3,Tap4,Tap5,Tap6+1],[Tap1,Tap2,Tap3,Tap4,Tap5,Tap6−1],}

At block 804, the FOM is measured at each row for neighbor rows in a neighborhood in the neighbors array if it is not already in the Tabu list. A numerical example for a neighborhood (for example, the first three rows in the neighbors array) with Tap1 (third row) set to 50 is shown below:
[51, 39, 28, 15, 15, 8]
[49, 39, 28, 15, 15, 8]
[50, 40, 28, 15, 15, 8]

If the FOM is greater than the BestCurrentFOM, the FOM is stored as the BestCurrentFOM and the BestCurrentTapSolution is neighbor.

At block 806, if no neighbors are found where the FOM is greater than the BestCurrentFOM, then move to max FOM neighbor from the current neighbors list. For example, BestCurrentFOM is 80 and FOMs for Neighbors 1-3 is 76, 72 and 78 is shown below:

| Item | Tap Settings | FOM |
|---|---|---|
| BestCurrentTapSolution | [50, 39, 28, 15, 15, 8] | 80 (BestCurrentFOM) |
| Neighbor 1 | [51, 39, 28, 15, 15, 8] | 76 |
| Neighbor 2 | [49, 39, 28, 15, 15, 8] | 72 |
| Neighbor 3 | [50, 40, 28, 15, 15, 8] | 78 |

In the next iteration of the Tabu search, the BestCurrentTapSolution is changed from [50, 39, 28, 15, 15, 8] with a FOM=80 to [50, 40, 28, 15, 15, 8] with a FOM=78 because the best neighbor (of neighbors 1-3) is Neighbor 3 with a FOM of 78.

At block 808, if a stop search condition is met, the search is stopped and processing continues with block 810. If the stop search condition is not met, processing continues with block 800 to perform another search. The stop search conditions include BestCurrentFOM greater than FOMThreshold, TabuSearchCount greater than SearchThreshold or BestCurrentFOM has not been updated in the past 4 searches.

The SearchThreshold is the maximum number of neighborhoods to search. In an embodiment, the SearchThreshold is six.

At block 810, the per tap settings are programmed to the BestCurrentTapSolution.

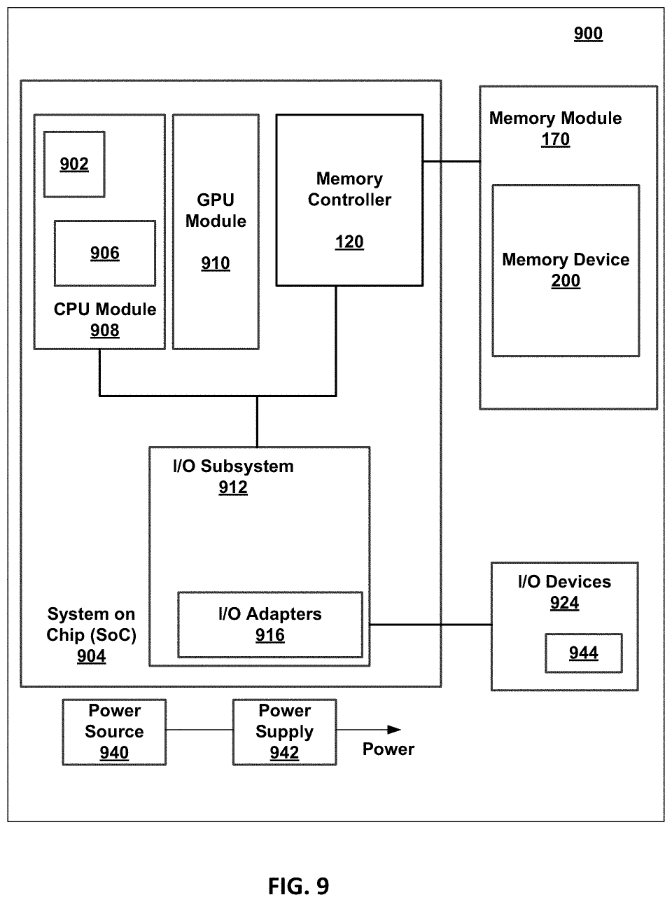

FIG. 9 is a block diagram of an embodiment of a computer system 900 that includes the memory module 170 that includes the memory device 200. Computer system 900 can correspond to a computing device including, but not limited to, a server, a workstation computer, a desktop computer, a laptop computer, and/or a tablet computer.

The computer system 900 includes a system on chip (SOC or SoC) 904 which combines processor, graphics, memory, and Input/Output (I/O) control logic into one SoC package. The SoC 904 includes at least one Central Processing Unit (CPU) module 908, a memory controller 120, and a Graphics Processor Unit (GPU) 910. In other embodiments, the memory controller 120 can be external to the SoC 904. The CPU module 908 includes at least one processor core 902, and a level 2 (L2) cache 906.

Although not shown, each of the processor core(s) 902 can internally include one or more instruction/data caches, execution units, prefetch buffers, instruction queues, branch address calculation units, instruction decoders, floating point units, retirement units, etc. The CPU module 908 can correspond to a single core or a multi-core general purpose processor, such as those provided by Intel® Corporation, according to one embodiment.

The Graphics Processor Unit (GPU) 910 can include one or more GPU cores and a GPU cache which can store graphics related data for the GPU core. The GPU core can internally include one or more execution units and one or more instruction and data caches. Additionally, the Graphics Processor Unit (GPU) 910 can contain other graphics logic units that are not shown in FIG. 9, such as one or more vertex processing units, rasterization units, media processing units, and codecs.

Within the I/O subsystem 912, one or more I/O adapter(s) 916 are present to translate a host communication protocol utilized within the processor core(s) 902 to a protocol compatible with particular I/O devices. Some of the protocols that adapters can be utilized for translation include Peripheral Component Interconnect (PCI)-Express (PCIe); Universal Serial Bus (USB); Serial Advanced Technology Attachment (SATA) and Institute of Electrical and Electronics Engineers (IEEE) 1594 “Firewire”.

The I/O adapter(s) 916 can communicate with external I/O devices 924 which can include, for example, user interface device(s) including a display 944 and/or a touch-screen display, printer, keypad, keyboard, communication logic, wired and/or wireless, storage device(s) including hard disk drives (“HDD”), solid-state drives (“SSD”), removable storage media, Digital Video Disk (DVD) drive, Compact Disk (CD) drive, Redundant Array of Independent Disks (RAID), tape drive or other storage device. The storage devices can be communicatively and/or physically coupled together through one or more buses using one or more of a variety of protocols including, but not limited to, SAS (Serial Attached SCSI (Small Computer System Interface)), PCIe (Peripheral Component Interconnect Express), NVMe (NVM Express) over PCIe (Peripheral Component Interconnect Express), and SATA (Serial ATA (Advanced Technology Attachment)). The display 944 to display data stored in the plurality of memory devices 200 in the memory module 170.

Additionally, there can be one or more wireless protocol I/O adapters. Examples of wireless protocols, among others, are used in personal area networks, such as IEEE 802.15 and Bluetooth, 4.0; wireless local area networks, such as IEEE 802.11-based wireless protocols; and cellular protocols.

Power source 940 provides power to the components of computer system 900. More specifically, power source 940 typically interfaces to one or multiple power supplies 942 in computer system 900 to provide power to the components of computer system 900. In one example, power supply 942 includes an AC to DC (alternating current to direct current) adapter to plug into a wall outlet. Such AC power can be renewable energy (e.g., solar power) power source 940. In one example, power source 940 includes a DC power source, such as an external AC to DC converter. In one example, power source 940 or power supply 942 includes wireless charging hardware to charge via proximity to a charging field. In one example, power source 940 can include an internal battery or fuel cell source.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to the disclosed embodiments and implementations of the invention without departing from their scope.

Therefore, the illustrations and examples herein should be construed in an illustrative, and not a restrictive sense. The scope of the invention should be measured solely by reference to the claims that follow.

What is claimed is:

1. A memory controller comprising:
Input/Output interface logic to couple to a memory device; and
a Memory Training Engine (MTE) to perform Decision feedback equalization (DFE) training in a DFE circuit in the memory device to select values of tap coefficients for taps in the DFE circuit, the MTE to perform a first search to identify initial values for the tap coefficients and to perform a second search using the initial values for tap coefficients to find final values for the tap coefficients.

2. The memory controller of claim 1, wherein the first search is faster than the second search.

3. The memory controller of claim 1, wherein the second search is more accurate than the first search.

4. The memory controller of claim 1, wherein the first search is a modified binary search.

5. The memory controller of claim 1, wherein the second search is a Tabu search.

6. The memory controller of claim 1, wherein the Memory Training Engine (MTE) to perform Decision feedback equalization (DFE) training during initialization of the memory device.

7. The memory controller of claim 1, wherein the Memory Training Engine (MTE) to perform Decision feedback equalization (DFE) training during operation of the memory device upon changes to continuous time linear equalization (CTLE).

8. The memory controller of claim 1, wherein the Memory Training Engine (MTE) to perform Decision feedback equalization (DFE) training during operation of the memory device upon changes to On Die Termination (ODT).

9. A system comprising:
a memory device; and
a memory controller, the memory controller comprising:
Input/Output interface logic to couple to a memory device; and
a Memory Training Engine (MTE) to perform Decision feedback equalization (DFE) training in a DFE circuit in the memory device to select values of tap coefficients for taps in the DFE circuit, the MTE to perform a first search to identify initial values for the tap coefficients and to perform a second search using the initial values for tap coefficients to find final values for the tap coefficients.

10. The system of claim 9, wherein the first search is faster than the second search.

11. The system of claim 9, wherein the second search is more accurate than the first search.

12. The system of claim 9, wherein the first search is a modified binary search.

13. The system of claim 9, wherein the second search is a Tabu search.

14. The system of claim 9, further comprising one or more of:
at least one processor communicatively coupled to the memory controller;
a display communicatively coupled to at least one processor; or
a power supply to provide power to the system.

15. A method comprising:
performing, by a Memory Training Engine (MTE) in a memory controller, a first search to identify initial values for tap coefficients for taps in a DFE circuit in a memory device; and
performing, by a Memory Training Engine (MTE), a second search using the initial values for tap coefficients to find final values for the tap coefficients.

16. The method of claim 15, wherein the first search is faster than the second search.

17. The method of claim 15, wherein the second search is more accurate than the first search.

18. The method of claim 15, wherein the first search is a modified binary search.

19. The method of claim 15, wherein the second search is a Tabu search.

20. The method of claim 15, wherein the Memory Training Engine (MTE) to perform Decision feedback equalization (DFE) training during initialization of the memory device.
